(19) United States
(12) Patent Application Publication
(10) Pub. No.: US 2013/0015589 A1
(43) Pub. Date: Jan. 17, 2013

(54) CHIP-ON-PACKAGE STRUCTURE FOR MULTIPLE DIE STACKS

(71) Applicants: Chih-Chin Liao, Changhua County (TW); Chin-Tien Chiu, Taichung City (TW); Cheeman Yu, Fremont, CA (US); Suresh Kumar Upadhyayula, San Jose, CA (US); Wen Cheng Li, Taichung City (TW); Zhong Lu, Shanghai (CN)

(72) Inventors: Chih-Chin Liao, Changhua County (TW); Chin-Tien Chiu, Taichung City (TW); Cheeman Yu, Fremont, CA (US); Suresh Kumar Upadhyayula, San Jose, CA (US); Wen Cheng Li, Taichung City (TW); Zhong Lu, Shanghai (CN)

(21) Appl. No.: 13/265,662

(22) PCT Filed: Jul. 14, 2011
(86) PCT No.: PCT/CN2011/077134

§ 371 Date: Oct. 21, 2011

(51) Int. Cl. H01L 25/065

(52) U.S. Cl. 257/777; 257/E25.011

(57) ABSTRACT

A multi-die semiconductor device is disclosed. The device may include one or more first-sized die on a substrate and one or more second-sized die affixed over the one or more first-sized die. The second-sized die may have a larger footprint than the first-sized die. An internal molding compound may be provided on the substrate having a footprint the same size as the second-sized die. The second-sized die may be supported on the internal molding compound. Thereafter, the first and second-sized die and the internal molding compound may be encapsulated in an external molding compound.

### BACKGROUND

1. Field

The present technology relates to semiconductor packaging.

2. Description of Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated from so-called 3-D semiconductor devices. Such multi-die devices include for example a system-in-a-package (SiP) or a multichip package (MCP), where a plurality of different types of semiconductor die are packaged on a substrate in a stacked configuration. For example, it is known to provide an MCP having a stacked configuration including flash memory die (NAND), a controller (ASIC) and embedded flash management firmware (DRAM (DDR/SDR)). Other types of semiconductor die may be used in such multi-die devices.

Prior art FIGS. 1-3 illustrate top, side and edge views of a multi-die device 20 including for example NAND flash memory, DDR DRAM and an ASIC controller. One problem with providing such a package is that each of these types of die are different sizes. In prior art FIGS. 1-3, the larger flash memory die 22 are mounted and wire bonded to a substrate 24. Thereafter, the smaller DRAM 28 and controller die 30 are mounted on top of the memory die 22 and then wirebonded to the substrate 24. In the example shown, there are a pair of memory die 22 and four DRAM 28, though there may be more or less of each type in further examples. In FIGS. 1-3, the controller die 30 is electrically coupled to the substrate via an interposer 34 to facilitate the required number of electrical connections between the controller die 30 and the substrate 24.

In FIGS. 1-3, the DRAM 28 are stacked without offset. In order to allow wire bonding to die bond pads 36 on each DRAM 28, the DRAM are separated by a film 38 (FIGS. 2 and 3). In order to construct the DRAM stack, a die is mounted and wire bonded, and then a layer of the film is applied, with a portion of the wire bond connected to the die bond pad 36 embedded in the film layer 38. The next die is then affixed to the film layer and the process is repeated.

One problem with the multi-die device 20 shown in FIGS. 1-3 is that long wires are required to electrically couple the DRAM 28 to the substrate 24. Long wires may create a risk of wire sag and electrical short, either wire-to-wire short, or wire-to-memory die edge short. Moreover, DRAM 28 have high frequency/high speed signal transfer requirements, and the long wires to the DRAM 28 may impair electrical and signal transfer performance of the multi-die device 20.

Prior art FIGS. 4 and 5 illustrate top and edge views of an alternative multi-die device 20. In this example, the DRAM 28, controller 30 and interposer 34 are mounted on the substrate 24. This design solves the above-described problems by shortening the wire bonds connecting the DRAM 28 to the substrate. However, the design of FIGS. 4 and 5 presents a problem of die cracking. In particular, the memory die 22 are larger than the DRAM 28, and hang over the edges of DRAM 28. As such, the edges of the DRAM 28 act as a fulcrum, creating stresses in the memory die along the line where the memory die extend out beyond the footprint of the DRAM 28. These stresses may result in the cracking of the memory die 22.

It is known to provide a film in the gap between the substrate 24 and overhanging memory die 22, but the use of such a film presents problems such as for example a “popcorn effect,” where air and moisture get into the film, and then expand when the device 20 is heated.

This can result in separation of the film from the substrate, damage to the DRAM 28 and/or memory die 22, and possible electrical shorting of any wires which become exposed due to the expansion of the air and moisture.

### DESCRIPTION OF THE DRAWINGS

FIG. 1 is a prior art top view of a conventional semiconductor device including DRAM stacked on top of memory die.

FIG. 2 is a prior art side view of a conventional semiconductor device including DRAM stacked on top of memory die.

FIG. 3 is a prior art edge view of a conventional semiconductor device including DRAM stacked on top of memory die.

FIG. 4 is a prior art top view of a conventional semiconductor device including memory die stacked on top of DRAM.

FIG. 5 is a prior art edge view of a conventional semiconductor device including memory die stacked on top of DRAM.

FIG. 6 is a flowchart for assembly of a multi-die device according to embodiments of the present disclosure.

FIG. 7 is a top view of a multi-die device according to embodiments of the present disclosure during a first phase of assembly.

FIG. 8 is a side view of the multi-die device of FIG. 7.

FIG. 9 is an edge view of the multi-die device of FIG. 7.

FIG. 10 is a top view of a multi-die device according to embodiments of the present disclosure during a second phase of assembly.

FIG. 11 is a side view of the multi-die device of FIG. 10.

FIG. 12 is an edge view of the multi-die device of FIG. 10.

FIG. 13 is a top view of a multi-die device according to embodiments of the present disclosure during a third phase of assembly.

FIG. 14 is a side view of the multi-die device of FIG. 13.

FIG. 15 is an edge view of the multi-die device of FIG. 13.

FIG. 16 is a top view of a multi-die device according to embodiments of the present disclosure during a fourth phase of assembly.

FIG. 17 is a side view of the multi-die device of FIG. 16.

FIG. 18 is an edge view of the multi-die device of FIG. 16.

FIG. 19 is a top view of a multi-die device according to embodiments of the present disclosure during a fifth phase of assembly.

FIG. 20 is a side view of the multi-die device of FIG. 19.

FIG. 21 is an edge view of the multi-die device of FIG. 19.

FIG. 22 is a top view of an alternative die arrangement on a multi-die device according to embodiments of the present disclosure.

FIG. 23 is a side view of the multi-die device of FIG. 22.

FIG. 24 is a top view of a further alternative die arrangement on a multi-die device according to embodiments of the present disclosure.

FIG. 25 is a side view of the multi-die device of FIG. 24.

FIG. 26 is a top view of a further alternative die arrangement on a multi-die device according to embodiments of the present disclosure.

FIG. 27 is a side view of the multi-die device of FIG. 26.

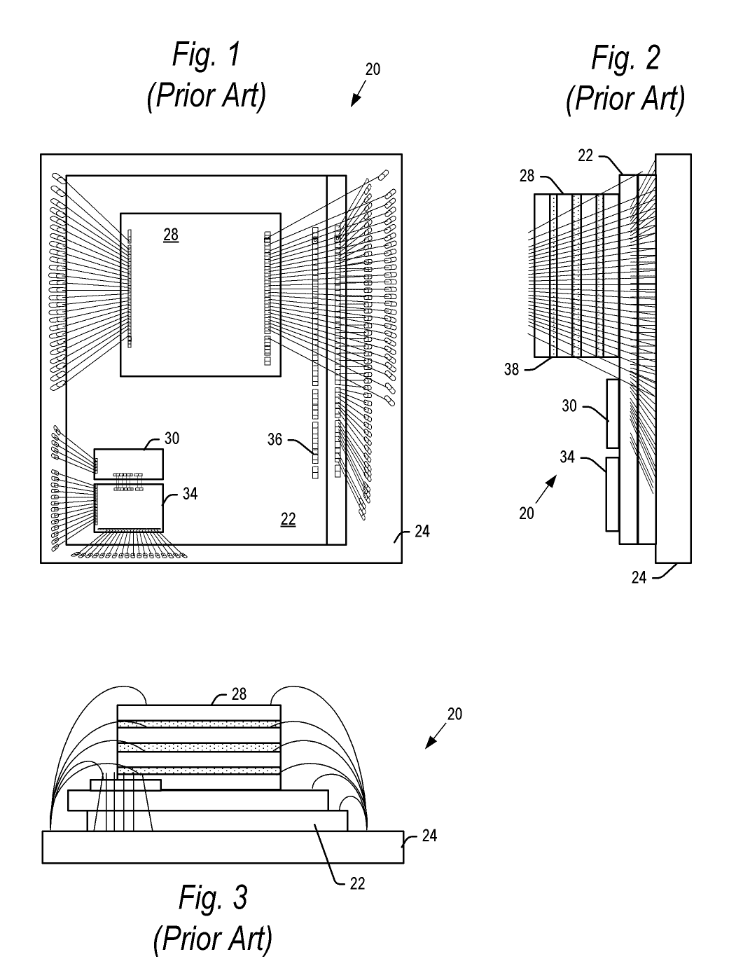

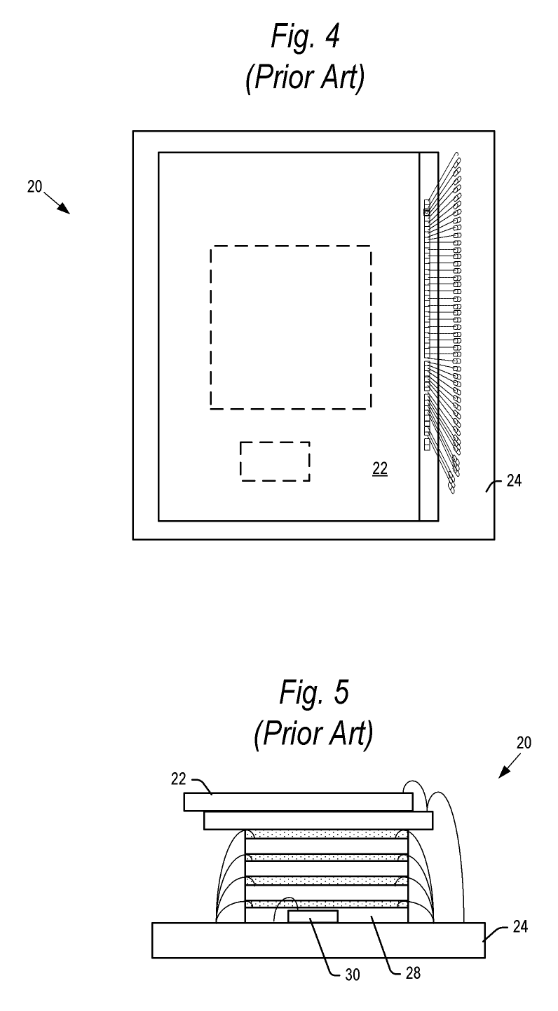

### DETAILED DESCRIPTION

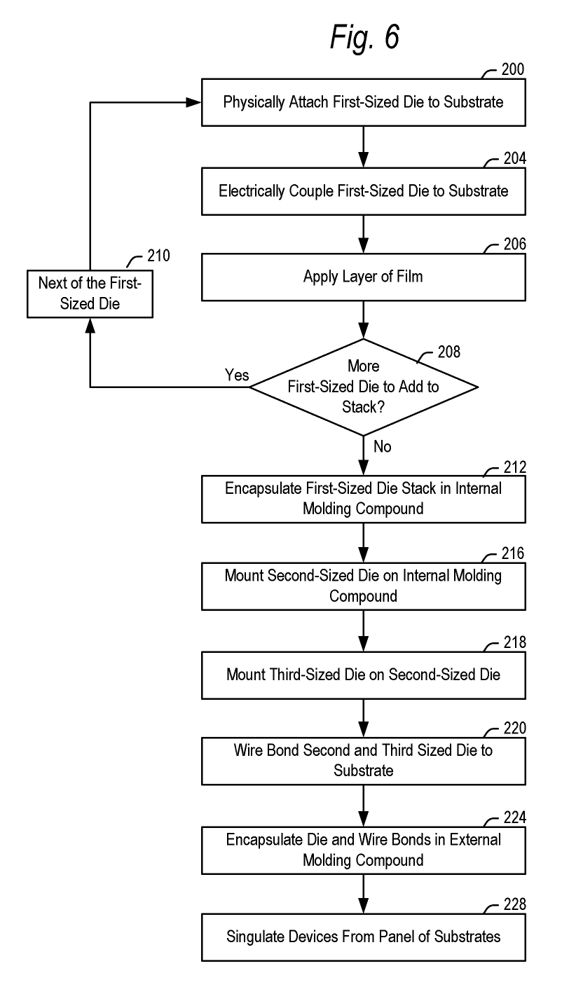

Embodiments will now be described with reference to FIGS. 6 through 27, which relate to a multi-die semiconductor device including semiconductor die of different sizes. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top,” “bottom,” “upper,” “lower,” “vertical” and/or “horizontal” are used herein for convenience and illustrative purposes only, and are not meant to limit the description of the invention inasmuch as the referenced item can be exchanged in position.

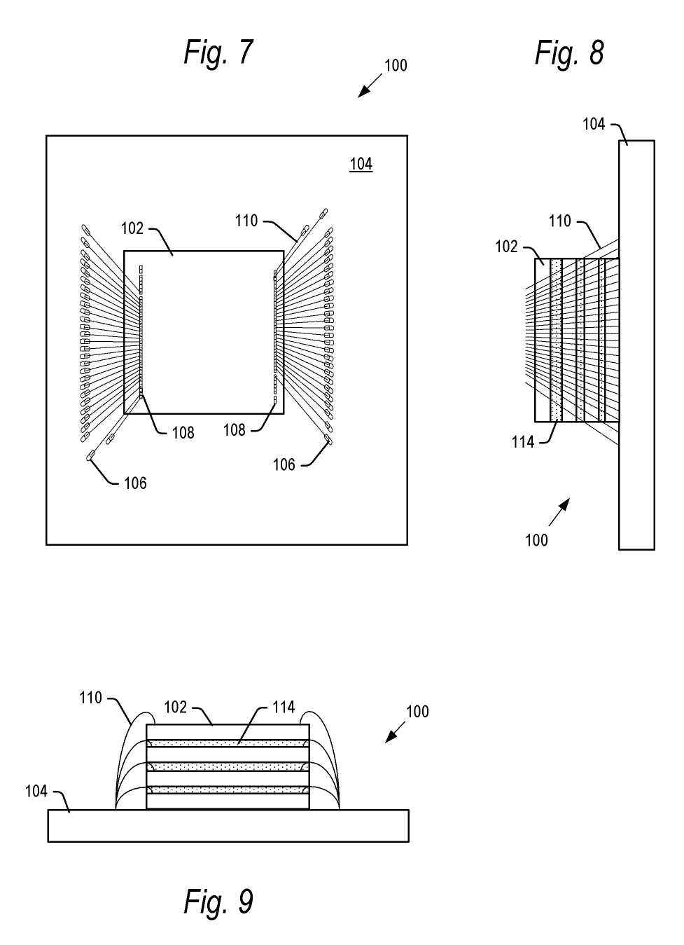

The process for forming a multi-die device 100 in accordance with an embodiment of the present system will now be described with reference to the flowchart of FIG. 6, and the various views of FIGS. 7 through 27 which show the device 100 in various stages of fabrication. Referring initially to the top, side and edge views of FIGS. 7-9, respectively, one or more of a first-sized semiconductor die 102 may be coupled to a substrate 104 in steps 200-210. In the following examples, the first-sized semiconductor die may be a DRAM, such as for example DDR or SDR. However, it is understood that the first-sized die 102 may be other semiconductor die in further embodiments.

Although not shown, substrate 104 may be part of a panel of substrates so that the semiconductor devices according to the present disclosure may be batch processed for economies of scale. Although fabrication of a single semiconductor device 100 is described below, it is understood that the following description may apply to all devices formed on the substrate panel. The substrate 104 may be a variety of different chip carrier mediums, including a printed circuit board (PCB), a leadframe or a tape automated bonded (TAB) tape. Where substrate 104 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like.

The conductive layers may be formed of copper or copper alloys, plated copper or plated copper alloys, Alloy 42 (42FE/58NI), copper plated steel or other metals or materials known for use on substrates. The conductive layers may be etched into a conductance pattern as is known for communicating signals between the semiconductor die in device 100 and an external device (not shown). Substrate 104 may additionally include exposed metal portions forming contact pads 106 on an upper surface of the substrate 104. The number of contact pads 106 shown is by way of example only, and there may be more or less contact pads in further embodiments. Where the semiconductor package is a land grid array (LGA) package, contact fingers (not shown) may also be defined on a lower surface of the substrate 104. The contact pads 106 and/or contact fingers may be plated with one or more gold layers, for example in an electroplating process as is known in the art.

In step 200, a first of the first-sized die 102 are mounted to substrate 104. The die 102 may be mounted to substrate 104 via a die attach adhesive in a known adhesive or eutectic die bond process. Die 102 may include die bond pads 108 formed along one or more edges of die 102. It is understood that the number of die bond pads 108 shown is by way of example and there may be more or less die bond pads 108 in die 102 in further embodiments.

In step 204, the die bond pads 108 of die 102 may be electrically coupled to respective contact pads 106 of substrate 104. In embodiments, this may be done via bond wires 110 in a known wire bond process. In further embodiments, at least the bottom die 102 (directly adjacent the substrate 104) may be electrically coupled to the substrate via solder balls in a known flip-chip bonding process.

In a wire bonded embodiment, in step 206, a film layer 114 is applied on an upper surface of the bottom die 102 (i.e., a surface opposite the surface attached to the substrate 104). The film layer 114 may for example be an electrically insulative adhesive epoxy of known composition available for example from Henkel Corporation, having headquarters in Headquarters in Dusseldorf, Germany. The film layer 114 may be applied as a viscous liquid, which remains in that state until cured in a reflow process explained hereinafter. In embodiments, the film layer 114 is applied as a liquid, but has a sufficiently high viscosity to mechanically support a second semiconductor die placed on layer 114 as explained hereinafter. In embodiments, the viscosity may be for example about 1-2×106 centipoise, but it is understood that the viscosity may be higher or lower than that in alternative embodiments. The film layer 114 may be the same as or different from the material used to attach the bottom die 102 to the substrate 104.

In an alternative embodiment, spacer balls may be provided within the film layer 114. The spacer balls may be polymeric spheres that act as spacers between the a first die 102 and a second die 102 mounted thereon as explained hereinafter. Such spacer balls are known in the art, and are disclosed for example in U.S. Pat. No. 6,650,019, entitled, “Method of Making a Semiconductor Package Including Stacked Semiconductor Die,” which patent is incorporated herein by reference in its entirety.

As best seen in FIG. 9, the film layer 114 is applied such that the wire bonds 110 are partially buried within the layer 114. Namely, the portion of bond wires 110 adjacent die bond pads 108 are buried within film layer 114. As film layer 114 is applied only over the surface of die 102, portions of the wire 110 extending outside of the footprint of die 102 are not embedded within film layer 114.

In step 208, it is determined whether more of the first-sized die 102 are to be included in the group of one or more first-sized die 102. If so, the next die is retrieved in step 210, and the process steps 200-210 are repeated. This process continues until the desired number of first-sized die 102 are provided in a die stack. In FIGS. 7-9, a stack of four first-sized die 102 are shown. There may be more or less than four die 102 in further embodiments. For the top die on the stack, the film layer 114 may be omitted. While the die 102 are shown stacked in an aligned orientation, it is understood that the die 102 may be stacked in with an offset in further embodiments. In such embodiments, it may be possible to omit the film layer 114.

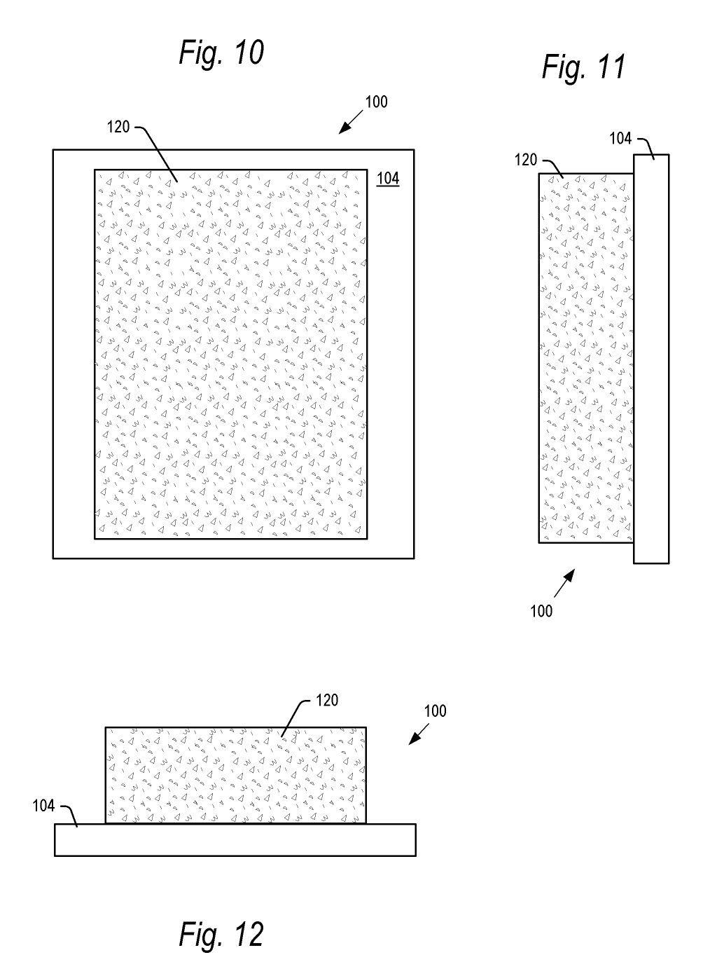

Referring now to the top, side and edge views of FIGS. 10-12, respectively, the stack of first-sized die 102 and wire bonds 110 may next be encapsulated in step 212 in a block of molding compound, referred to herein as internal molding compound 120. In embodiments, the encapsulation may be performed by transfer molding, using a known epoxy for example from Nitto Denko Corp. of Japan. In such an embodiment, discrete and separate amounts of internal molding compound are applied to each device 100 formed on the substrate panel (as opposed to a continuous layer of molding compound completely encapsulating the substrate panel). The encapsulation process may be by other technologies in further embodiments, including for example by FFT compression molding, explained below. Where done by FFT compression molding, a customized mold plate may be provided having discrete reservoirs of molten resin so that, when the panel is immersed into the molten resin, discrete and separate amounts of internal molding compound are applied to each device 100 formed on the substrate panel.

An example of internal molding compound 120 is shown in the top, side and edge views of FIGS. 10-12, respectively. In the embodiments shown, all of the first-sized die 102 and wire bonds 110 are encapsulated in a block of internal molding compound 120.

As explained below, one or more second-sized die, such as a memory die, may be mounted on top of the stack of first-sized die, where the second-sized die may be larger than the first-sized die. A purpose of the internal molding compound 120 is to provide support for the second-sized die, and prevent stresses from building in the second-sized die upon mounting a larger second-sized die over a smaller first-sized die. One configuration of internal molding compound 120 that alleviates substantially all cracking stresses in the second-sized die is to provide a single block of internal molding compound 120 having a footprint (length and width) that matches the footprint of the second-sized die mounted thereon. This is the embodiment shown in FIGS. 10-12.

However, it is understood that the internal molding compound 120 may be provided in a wide variety of configurations with the provision that a second-sized die may be supported on and by the internal molding compound 120 such that stresses within the mounted second-sized die are maintained below some predetermined level. This predetermined level will be the level below which there is little or no risk of the second-sized die cracking.

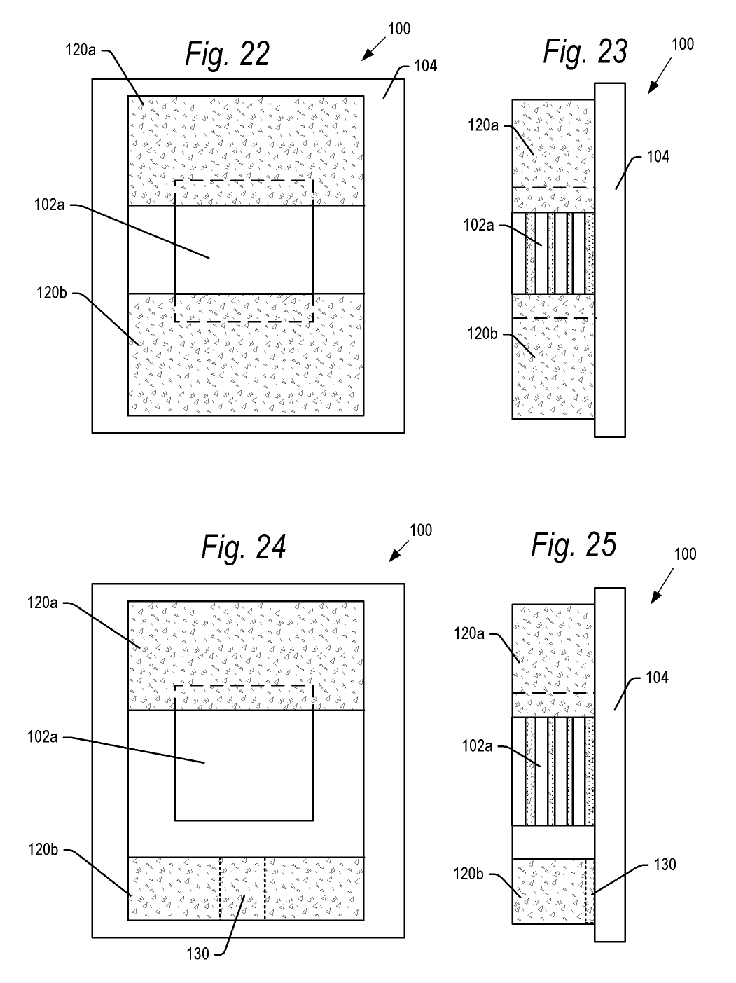

One such alternative embodiment is shown in the top and side views of FIGS. 22-23. In this embodiment, the internal molding compound 120 is applied in two separate blocks 120a and 120b. The blocks 120a, 120b are spaced from each other so that a portion 102a of the stack of first-sized die 102 is exposed and not covered by internal molding compound 120. However, the internal molding compound blocks 120a, 120b may be sized and positioned so that, taken together, they may have a combined footprint matching the footprint of the second-sized die mounted thereon as explained hereinafter. The two blocks of internal molding compound 120a and 120b may have the same height as each other, so as to support the second-sized die in a plane parallel to the substrate 104. In further embodiments, the internal molding compound 120 may have a larger or smaller footprint than the die supported thereon.

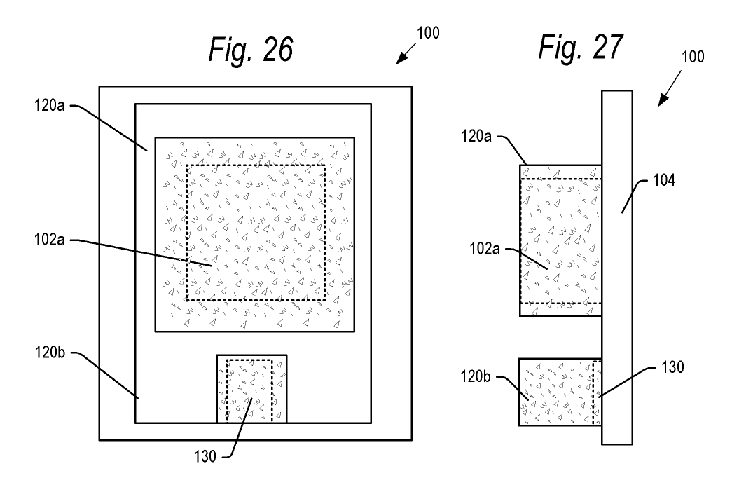

The top and side views of FIGS. 24 and 25 show a further embodiment of internal molding compound 120. As explained hereinafter, a third-sized die, such as a controller chip 130, may be mounted on the substrate 104. In embodiments, that controller die may be wire bonded to the substrate and then encapsulated in the single block of internal molding compound 120 shown in FIGS. 10-12. In the alternative embodiment shown in FIGS. 24 and 25, the internal molding compound 120 is applied in two blocks 120a and 120b with a first block 120a provided over, partially over or near the stack of first-sized die 102, and the second block 120b provided over, partially over or near the controller 130. FIGS. 26 and 27 are top and side views of a further embodiment similar to FIGS. 24 and 25, but where the internal molding compound 120 forms blocks, or islands, around the die 102 and 130. The second-sized die may be supported on one or the other of the islands, or on both islands together.

It is understood that the internal molding compound 120 may be provided in a wide variety of other configurations, with the provision that the internal molding compound 120 support the second-sized die in a way that prevents stresses in the second-sized die that can potentially crack the second-sized die. These configurations may be one or more rectangular shaped blocks as shown in FIGS. 10-12 and 22-27, but the blocks of internal molding compound 120 may have rounded edges in further embodiments. As explained below, a second encapsulation process is performed that completely encases all die in device 100. Thus, it is not necessary that the internal molding compound 120 cover all, or even any, of the first-sized die 102 and/or the wire bonds 110 off of the first-sized die 102.

Referring again to the flowchart of FIG. 6, in step 216, one or more of a second-sized die 126 may be mounted on and supported by the internal molding compound 120. The die 126 may be mounted on the molding compound 120 via a die attach adhesive in a known adhesive or eutectic die bond process. As indicated above, the second-sized die may for example be a flash memory chip, such as NAND memory die. The second-sized die may be other types of die in further embodiments. In embodiments, the second-sized die has a larger footprint than the first-sized die. In step 218, a third-sized die 130 may be mounted on the top die of the second-sized die. The third-sized die may for example be a controller chip, such as an ASIC. An interposer 132 may also be provided adjacent the third-sized die 130 in embodiments to facilitate electrical connection of the third-sized die 130 to the substrate 104. The interposer may be omitted in further embodiments.

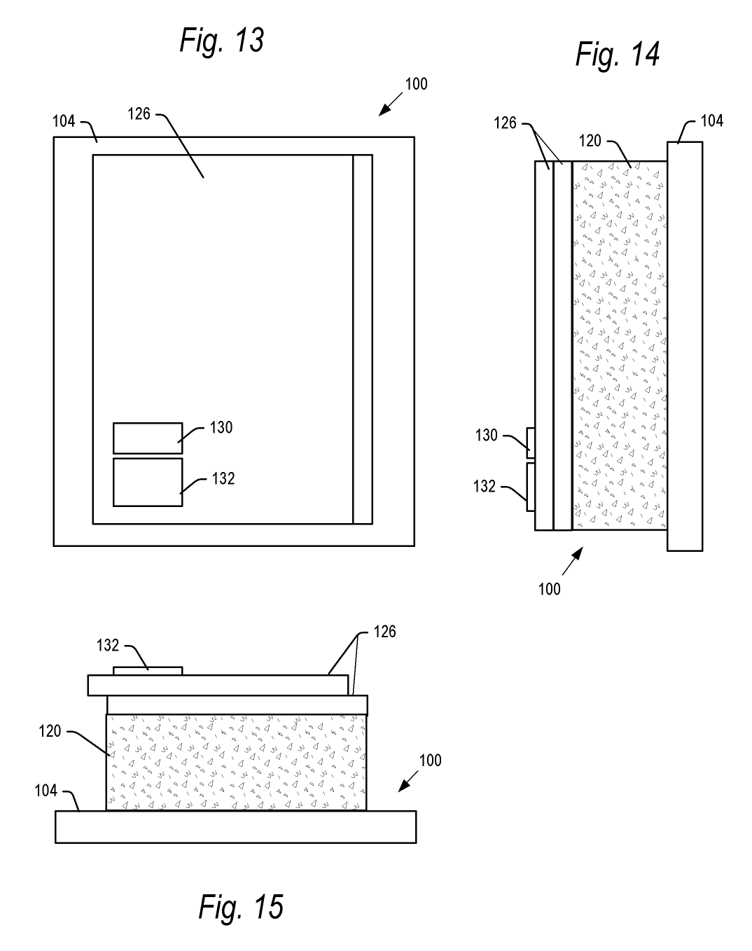

An embodiment showing the second-sized die mounted on the molding compound 120, and the third-sized die mounted on the top of the second-sized die is shown in the top, side and edge views of FIGS. 13-15. In the example shown, there may be two, second-sized die 126. However, there may be only a single second-sized die, or there may be more than two second-sized die in further embodiments.

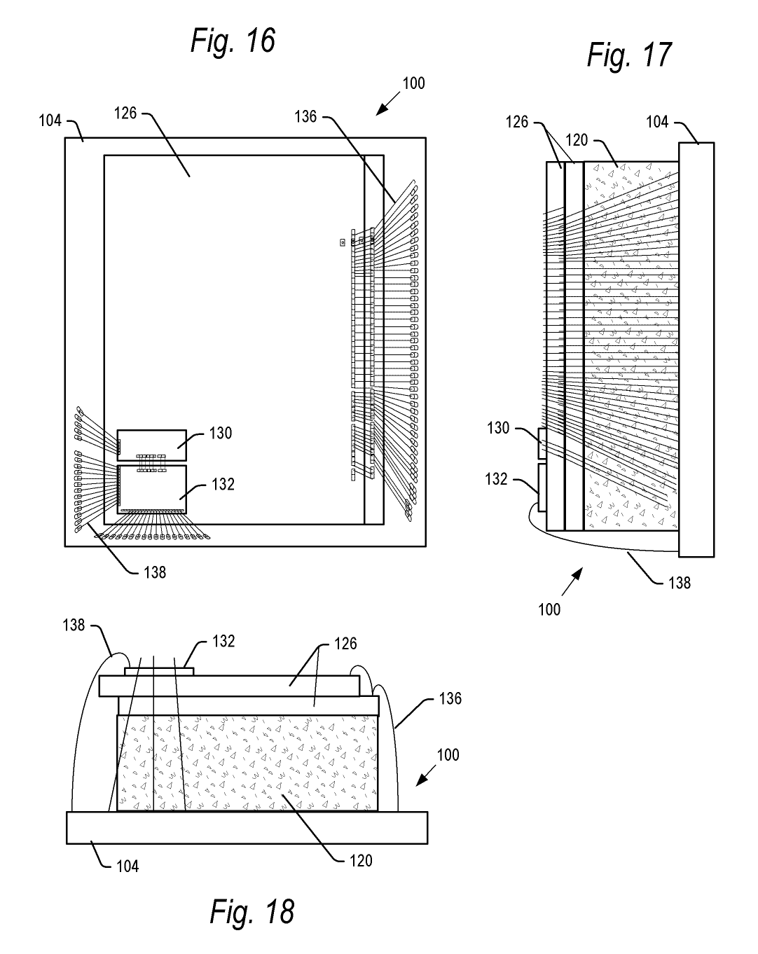

In step 220, the second-sized die 126 and third-sized die 130 may be wire bonded to the contact pads 106 of the substrate 104 via wire bonds 136, 138 as shown in the top, size and edge views of FIGS. 16-18. The number of wire bonds 136, 138 shown is by way of example only, and may vary above or below the number shown in further embodiments.

Instead of the second-sized die 126 and third-sized die 130 being mounted and then wire bonded, the second-sized die 126 may be mounted to the molding compound 120 and wire bonded to the substrate 106. Thereafter, the third-sized die 130 may be mounted to the second-sized die and then the third-sized die may be wire bonded to the substrate 106. As noted above, in a further embodiment, the third-sized die may alternatively be mounted directly to the substrate 106. In such embodiments, the third-sized die 130 would be mounted to the substrate 106, and wire bonded to the substrate 106, prior application of the internal molding compound 120.

Where there are more than one second-sized die 126, the die may be stacked in an offset configuration as seen for example in FIGS. 16 and 18 to facilitate wire bonding. The second-sized die may be in an aligned stack in a further embodiment. In such embodiments, each second-sized die may be separated from each other by a film layer (such as film layer 114) to allow wire bonding to each die in the stack of second-sized die. In such embodiment, the die stack may be built by mounting a second-sized die, wire bonding it, applying a film layer, and then mounting the next die in the stack.

As noted, in embodiments, the second-sized die 126 has a larger footprint than the first-sized die 102, so that the molding compound 120 supports the second-side die 126 in accordance with the present disclosure. However, it is contemplated that the second-sized die 126 could have the same, or even smaller, footprint as the first-sized die, but be mounted in such a way that one side of the second-sized die 126 sticks out over an edge of the first-sized die. In such embodiments, the molding compound 120 may be provided under the protruding edge of the second-sized die 126 to prevent cracking stresses from building in the second-sized die due to the overhang. The third-sized die 130 may be smaller than both the first-sized die 102 and/or second-sized die 126, though it need not be in further embodiments.

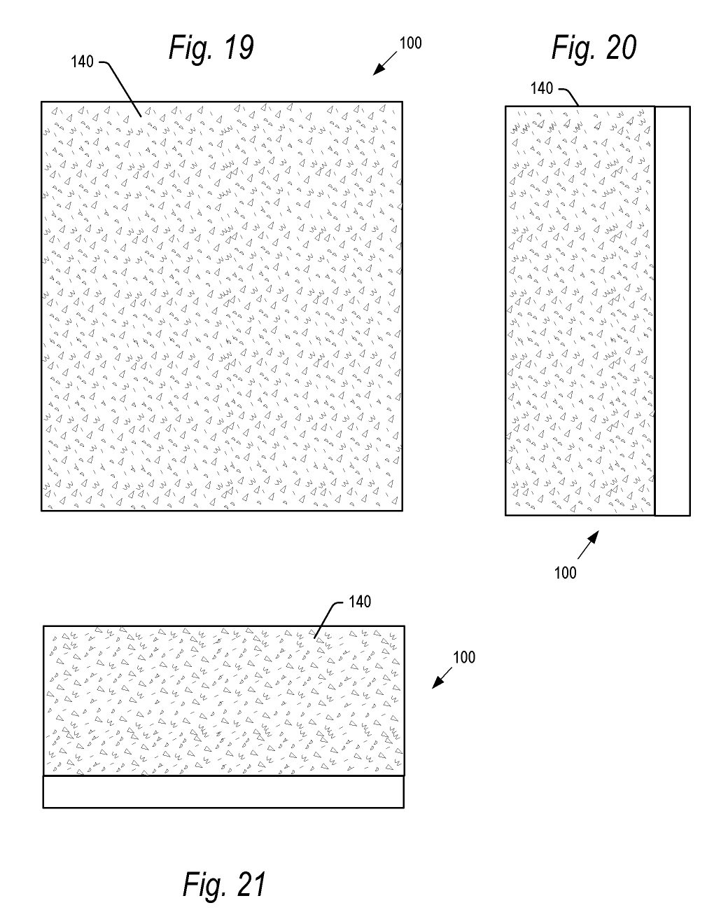

In step 224, a second encapsulation process may be performed to apply a second layer of molding compound, referred to herein as the external molding compound 140. The external molding compound 140 may be the same composition used for internal molding compound 120, though compound 140 may be different than compound 120 in further embodiments. The second encapsulation process by external molding compound 140 completely encapsulates the first, second and third-sized die, all wire bonds, and the internal molding compound 120. This may complete the fabrication of the device 100. An embodiment of the device 100 including the external molding compound 140 is shown in the top, side and edge views of FIGS. 19-21.

In embodiments, the external molding compound 140 encapsulation process may be performed by transfer molding, using an epoxy known for example from Nitto Denko Corp. of Japan. In such an embodiment, each device 100 on the panel of substrates may be encapsulated together in a single layer of molding compound to cover all devices 100 on the panel of substrates.

In a further embodiment, instead of transfer molding, the external molding compound 140 encapsulation process may be performed by FFT (Flow Free Thin) compression molding. Such an FFT compression molding process is known and described for example in a publication by Matsutani, H. of Towa Corporation, Kyoto, Japan, entitled “Compression Molding Solutions For Various High End Package And Cost Savings For Standard Package Applications,” Microelectronics and Packaging Conference, 2009, which publication is incorporated by reference herein in its entirety. In general, an FFT compression machine makes use of a technique where the panel of substrates is immersed in a mold containing a molten resin. The resin fills all voids on the panel and encapsulates each device together in a single layer of molding compound on the panel of substrates, without exerting pressure on the die or bond wires.

After application of the external molding compound 140, the respective devices 100 on the panel of substrates may be singulated in step 228, to form finished multi-die devices 100.

As noted above, in embodiments, the first-sized die may be DRAM such as for example SDR, DDR1, DDR2, DDR3 or DDR4. The second-sized die may be flash memory such for example NAND, and the third-sized die may be a controller such as for example an ASIC. Other types of chips are contemplated for the first, second and/or third-sized die. In one such example, both the first and second-sized die may be flash memory, but of different sizes.

The above-embodiments disclose two different molding operations so that a larger set of die may be mounted on top of a smaller set of die without cracking stresses developing in the larger set of die. In the embodiments described above, no other larger die was supported on the third-sized die. As such, no internal molding compound was required around the third-sized die to support the die mounted thereon. In a further embodiment, one or more first-sized die may be mounted to the substrate, one or more larger second-sized die may be mounted on the first-sized die, and one or more larger still third-sized die may be mounted on the second-sized die. In such an embodiment, a first internal molding compound may be provided around the first-sized die to provide support for the second-sized die; a second internal molding compound may be provided around the second-sized die to provide support for the third-sized die, and then an external molding compound may be provided around the first, second and third-sized die.

This process may be further expanded in this way to include additional internal molding compound layers for fourth-sized die larger than the third-sized die, and possibly fifth-sized die larger than the fourth-sized die. Additional, still larger die are contemplated. Each mounting of a larger-sized die on a smaller-sized die may be facilitated by an internal molding compound around the smaller-sized die.

In summary, an embodiment of the present disclosure relates to a semiconductor device, comprising: a substrate; one or more first-sized die mounted and electrically coupled to the substrate; an internal molding compound formed on the substrate; one or more second-sized die mounted on the internal molding compound and electrically coupled to the substrate, the second-sized die having at least one edge overhanging an edge of the first-sized die, the overhanging edge of the second-sized die supported on the internal molding compound; and an external molding compound formed around the one or more first-sized die, the one or more second-sized die and the internal molding compound.

A further embodiment relates to a semiconductor device, comprising: a substrate; one or more first-sized die mounted and wire bonded to the substrate; an internal molding compound formed on the substrate; one or more second-sized die mounted on the internal molding compound and wire bonded to the substrate, the second-sized die having a larger footprint than the first-sized die, the portions of the second-sized die extending beyond the footprint of the first-sized die being supported on the internal molding compound; and an external molding compound formed around the one or more first-sized die, the one or more second-sized die and the internal molding compound.

A still further embodiment relates to a semiconductor device, comprising: a substrate; one or more DRAM die mounted and electrically coupled to the substrate; an internal molding compound formed on the substrate around the DRAM die; one or more flash memory die mounted over the one or more DRAM on the internal molding compound and electrically coupled to the substrate, the one or more flash memory die having a larger footprint than the DRAM die, the portions of the flash memory die extending beyond the footprint of the DRAM die being supported on the internal molding compound; a controller die electrically coupled to the substrate and mounted on one of the substrate and the one or more flash memory die; and an external molding compound formed around the one or more DRAM die, the one or more flash memory die, the controller die and the internal molding compound.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
one or more first-sized die mounted and electrically coupled to the substrate;
an internal molding compound formed on the substrate;
one or more second-sized die mounted on the internal molding compound and electrically coupled to the substrate, the second-sized die having at least one edge overhanging an edge of the first-sized die, the overhanging edge of the second-sized die supported on the internal molding compound; and
an external molding compound formed around the one or more first-sized die, the one or more second-sized die and the internal molding compound.

2. The semiconductor device of claim 1, wherein the internal molding compound is a single block of molding compound having a same footprint as the second-sized die.

3. The semiconductor device of claim 1, wherein the internal molding compound is two or more blocks of molding compound which together have a same footprint as the second-sized die.

4. The semiconductor device of claim 1, wherein the internal molding compound is one or more blocks of molding compound which together have a footprint larger than a footprint of the second-sized die.

5. The semiconductor device of claim 1, wherein the internal molding compound is one or more blocks of molding compound which together have a footprint smaller than a footprint of the second-sized die.

6. The semiconductor device of claim 1, wherein the internal molding compound encapsulates the one or more first-sized die.

7. The semiconductor device of claim 1, wherein the internal molding compound encapsulates only a portion of the one or more first-sized die.

8. The semiconductor device of claim 1, wherein the one or more first-sized die comprise one or more DRAM chips.

9. The semiconductor device of claim 1, wherein the one or more second-sized die comprise one or more flash memory chips.

10. The semiconductor device of claim 1, further comprising a third-sized die mounted on one of the substrate and second-sized die.

11. The semiconductor device of claim 10, wherein the one or more third-sized die comprise a controller chip.

12. The semiconductor device of claim 1, further comprising a third-sized die mounted on the substrate, the internal molding compound comprising a first block encapsulating a least a portion of the first-sized die, and the internal molding compound comprising a second block encapsulating at least a portion of the third-sized die.

13. A semiconductor device, comprising:
a substrate;
one or more first-sized die mounted and wire bonded to the substrate;
an internal molding compound formed on the substrate;
one or more second-sized die mounted on the internal molding compound and wire bonded to the substrate, the second-sized die having a larger footprint than the first-sized die, the portions of the second-sized die extending beyond the footprint of the first-sized die being supported on the internal molding compound; and
an external molding compound formed around the one or more first-sized die, the one or more second-sized die and the internal molding compound.

14. The semiconductor device of claim 13, wherein the internal molding compound is one or more blocks of molding compound which together have a same footprint as the second-sized die.

15. The semiconductor device of claim 13, wherein the internal molding compound is one or more blocks of molding compound which together have a footprint larger than a footprint of the second-sized die.

16. The semiconductor device of claim 13, wherein the internal molding compound is one or more blocks of molding compound which together have a footprint smaller than a footprint of the second-sized die.

17. The semiconductor device of claim 13, further comprising a third-sized die mounted on one of the substrate and second-sized die.

18. The semiconductor device of claim 17, wherein the one or more third-sized die comprise a controller chip.

19. The semiconductor device of claim 13, further comprising a third-sized die mounted on the substrate, the internal molding compound comprising a first block encapsulating a least a portion of the first-sized die, and the internal molding compound comprising a second block encapsulating at least a portion of the third-sized die.

20. A semiconductor device, comprising:
a substrate;
one or more DRAM die mounted and electrically coupled to the substrate;
an internal molding compound formed on the substrate around the DRAM die;
one or more flash memory die mounted over the one or more DRAM on the internal molding compound and electrically coupled to the substrate, the one or more flash memory die having a larger footprint than the DRAM die, the portions of the flash memory die extending beyond the footprint of the DRAM die being supported on the internal molding compound;
a controller die electrically coupled to the substrate and mounted on one of the substrate and the one or more flash memory die; and
an external molding compound formed around the one or more DRAM die, the one or more flash memory die, the controller die and the internal molding compound.

21. The semiconductor device of claim 20, wherein the internal molding compound is one or more blocks of molding compound which together have a same footprint as the DRAM die.

22. The semiconductor device of claim 20, wherein the internal molding compound is one or more blocks of molding compound which together have a footprint larger than a footprint of the DRAM die.

23. The semiconductor device of claim 20, wherein the internal molding compound encapsulates the one or more DRAM.

24. The semiconductor device of claim 20, wherein the one or more DRAM comprise a stack of four DRAM.

25. The semiconductor device of claim 20, wherein the one or more flash memory comprise a stack of two flash memory.

26. The semiconductor device of claim 20, wherein the controller die is mounted on the substrate and buried within the internal molding compound.
